(19) United States
(12) Patent Application Publication
(10) Pub. No.: US 2008/0242105 A1
(43) Pub. Date: Oct. 2, 2008

(54) Semiconductor manufacturing apparatus, semiconductor wafer manufacturing method using this apparatus, and recording medium having program of this method recorded therein

(75) Inventors: Tomoyasu Kai, Miyazaki (JP); Hiroyuki Baba, Miyazaki (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO., LTD., Tokyo (JP)

(21) Appl. No.: 12/076,127

(22) Filed: Mar. 13, 2008

(30) Foreign Application Priority Data
Mar. 27, 2007 (JP) 2007-081788

(51) Int. Cl. H01L 21/28; C23C 16/52; C23C 16/46

(52) U.S. Cl. 438/758; 118/719; 118/668; 257/E21.158

(57) ABSTRACT

Foreign particles are prevented from adhering to a semiconductor wafer in a semiconductor manufacturing apparatus including (a) a hot plate which heats a semiconductor wafer to increase its temperature and which has a suction/discharge hole through which a negative pressure is supplied to suck and hold said semiconductor wafer at a rear surface thereof, and through which a gas is ejected to control the increase in temperature of said semiconductor wafer; and (b) a film forming section which forms a film used for production of a semiconductor device on a front surface of the semiconductor wafer, wherein the gas is ejected from the suction/discharge hole when the hot plate is placed on the film forming section and the hot plate does not hold the semiconductor wafer.

### BACKGROUND OF THE INVENTION

1. Field of the Invention

The present invention relates to a semiconductor manufacturing apparatus including means for sucking and holding a preheated semiconductor wafer to form a film in a process of manufacturing a semiconductor device by using a semiconductor wafer, e.g., a sapphire wafer, to a semiconductor wafer manufacturing method using this apparatus, and to a recording medium having a program of this method recorded therein.

2. Description of the Related Art

In general, a manufacturing process for a semiconductor device using a sapphire wafer in which, e.g., silicon (Si) is epitaxially grown to laminate a thin-film element forming layer on a sapphire substrate composed of a sapphire (Al₂O₃) crystal can substantially cover a manufacturing process for a semiconductor device using a regular silicon wafer. Thus, the same semiconductor manufacturing apparatus can be shared so as to produce both product lines at a lower cost.

Conversely, when a manufacturing process for a semiconductor device using a silicon wafer is used to manufacture a semiconductor device using a sapphire wafer, a problem arises because the sapphire wafer is transparent and has a low absorption factor of radiant heat caused by, e.g., an infrared ray.

The low absorption factor of radiant heat characteristic of sapphire wafers has been addressed in conventional semiconductor manufacturing apparatuses by forming a thin film made of a light absorber on the rear surface or by pressing a conductor against the rear surface of the sapphire wafer. Then, the thin film is heated by using radiant heat or an eddy current based on, e.g., a lamp heating method or a high-frequency induction heating method to increase the temperature of the sapphire wafer based on heat conduction from the heated thin film, thereby preheating the sapphire wafer at this stage (see, e.g., Japanese Patent Application Laid-open No. 70313-1998, p. 4, paragraph 0019-p. 5, paragraph 0032, and FIGS. 3 and 4).

When performing such preheating, however, a warping problem occurs which makes it difficult to suck and hold the rear surface of the sapphire wafer using a negative pressure. That is, at a manufacturing step where atmospheric temperature is low, e.g., a preheating step for an atmospheric CVD (Chemical Vapor Deposition) apparatus used in an atmospheric CVD method, a temperature difference occurs between the front and rear surfaces of the sapphire wafer when the sapphire wafer is heated from one side, e.g., the rear side. Then, convex warping occurs in the heated sapphire wafer on the rear surface side where its outer peripheral part rises, and sucking and holding the rear surface of the sapphire wafer by using a negative pressure becomes difficult.

A solution to this problem was proposed in Japanese Patent Application No. 2006-194789 (not yet Laid-open). During a preheating step in which a hot plate is used to increase the temperature of a sapphire wafer, nitrogen (N₂) gas is ejected from a suction hole which is provided in the hot plate to suck and hold the sapphire wafer, thereby decreasing the rate of temperature rise at a central part of the sapphire wafer. Thus, the sapphire wafer is uniformly preheated and warping suppressed, the flattened rear surface of the sapphire wafer is sucked and held by supplying a negative pressure through the suction hole, and the sapphire wafer held by the hot plate is supplied to a film forming step based on the CVD method thus effecting a process operation.

However, although the technique of ejecting nitrogen gas from a suction/discharge hole, which serves as the suction hole and an ejection hole, to cool the central part of the sapphire wafer so as to suppress warping of the sapphire wafer is effective as a technology which can uniformly preheat a semiconductor wafer, such as a sapphire wafer, and which can facilitate holding the flattened semiconductor wafer based on suction to promote the process operation, a film is to be formed on a front surface of semiconductor wafer whose rear surface is sucked and held to the hot plate at a subsequent film forming step based on, e.g., the CVD method. Thus, a reaction product deposited on the semiconductor wafer at the time of film formation may be sucked due to even a small gap between the rear surface of the semiconductor wafer and the hot plate, and may enter an introduction tube through which the negative pressure or the nitrogen gas is supplied to the suction/discharge hole. Then, this reaction product may be discharged as a foreign particle when ejecting nitrogen gas at a subsequent preheating step and may adhere to the front surface or the rear surface of the semiconductor wafer thereby reducing the yield ratio at the time of film formation on the semiconductor wafer.

In view of the above-explained problem, it is an object of the present invention to provide means for preventing a foreign particle from adhering to a semiconductor wafer in a semiconductor manufacturing apparatus including a hot plate having a suction/discharge hole serving as a suction hole and an ejection hole.

### SUMMARY OF THE INVENTION

To solve the problem according to the present invention, there is provided a semiconductor manufacturing apparatus comprising a hot plate which heats a semiconductor wafer to increase its temperature and which has a suction/discharge hole through which a negative pressure is supplied to suck and hold said semiconductor wafer at a rear surface thereof, and through which a gas is ejected to control the increase in temperature of said semiconductor wafer; and a film forming section which forms a film used for production of a semiconductor device on a front surface of said semiconductor wafer whose rear surface is sucked and held by the hot plate, wherein said gas is ejected through the suction/discharge hole when the hot plate is placed on the film forming section and the hot plate does not hold said semiconductor wafer. The gas may be intermittently ejected through the suction/discharge hole.

To further solve the problem according to the present invention, there is provided a semiconductor manufacturing apparatus comprising a hot plate which heats a semiconductor wafer to increase its temperature and which has a suction/discharge hole through which a negative pressure is supplied to suck and hold said semiconductor wafer at a rear surface thereof, and through which a gas is ejected to control the increase in temperature of said semiconductor wafer; a film forming section which forms a film used for production of a semiconductor device on a front surface of the semiconductor wafer whose rear surface is sucked and held by the hot plate; means for determining (judging) whether the hot plate is placed on the film forming section or not; means for determining (judging) whether the semiconductor wafer is held by the hot plate or not; and means for ejecting the gas through the suction/discharge hole of the hot plate when the hot plate is determined to have been placed on the film forming section by said means for determining whether the hot plate is placed on the film forming section or not and when the semiconductor wafer is determined to be not held by the hot plate by said means for determining whether the semiconductor wafer is held by the hot plate or not. The semiconductor manufacturing apparatus may further comprise means for storing sequence data including an opening time during which the gas is ejected and a closing time during which the gas is interrupted written therein; and, in place of said means for ejecting the gas from the suction/discharge hole, means for reading the sequence data; and means for intermittently ejecting the gas from the suction/discharge hole based on the sequence data read.

To further solve the problem according to the present invention, there is provided a method of manufacturing a semiconductor wafer using a semiconductor manufacturing apparatus comprised of a hot plate which heats a semiconductor wafer to increase its temperature and which has a suction/discharge hole through which a negative pressure is supplied to suck and hold said semiconductor wafer at a rear surface thereof, and through which a gas is ejected to control the increase in temperature of said semiconductor wafer; and a film forming section which forms a film used for production of a semiconductor device on a front surface of said semiconductor wafer, the method comprising the steps of detecting whether or not the hot plate is placed on the film forming section; detecting whether or not the semiconductor wafer is held by the hot plate; and ejecting the gas from the suction/discharge hole of the hot plate placed on the film forming section when the hot plate is placed on the film forming section and the semiconductor wafer is not held by the hot plate. The method may comprise, in place of ejecting the gas from the suction/discharge hole, intermittently ejecting the gas from the suction/discharge hole.

To additionally solve the problem according to the present invention, there is provided a recording medium having a program which is recorded therein and which is executed by a control section of a semiconductor manufacturing apparatus comprised of a hot plate which heats a semiconductor wafer to increase its temperature and which has a suction/discharge hole through which a negative pressure is supplied to suck and hold said semiconductor wafer at a rear surface thereof, and through which a gas is ejected to control the increase in temperature of said semiconductor wafer; and a film forming section which forms a film used for production of a semiconductor device on a front surface of said semiconductor wafer, the program comprising the steps of determining whether or not the hot plate is placed on the film forming section; determining whether or not the semiconductor wafer is held by the hot plate; and ejecting the gas from the suction/discharge hole of the hot plate placed on the film forming section when it is determined that the hot plate is placed on the film forming section and the semiconductor wafer is not held by the hot plate. The program may include sequence data having an opening time in which the gas is ejected and a closing time in which the gas is interrupted written therein, and wherein the program comprises, in place of ejecting the gas from the suction/discharge hole, reading the sequence data; and intermittently ejecting the gas from the suction/discharge hole based on the sequence data read.

As a result, the present invention can remove foreign particles which might have been sucked into an introduction tube during a film forming step by using nitrogen gas ejected from the suction/discharge hole when the semiconductor wafer is not present. This avoids discharge of foreign particles when ejecting a gas through the suction/discharge hole which is used to control the increase in temperature of the semiconductor wafer during a preheating step. This prevents the foreign particle from adhering to the front surface or the rear surface of the semiconductor wafer thereby improving film quality at the time of film formation on the semiconductor wafer.

### BRIEF DESCRIPTION OF THE DRAWINGS

FIG. 1 is a schematic illustration of a semiconductor manufacturing apparatus according to an embodiment of the present invention;

FIG. 2 is a block diagram showing the semiconductor manufacturing apparatus according to the embodiment of FIG. 1;

FIG. 3 is a schematic illustration of a piping system according to the embodiment of FIG. 1;

FIGS. 4A-4D are schematic illustrations of a manufacturing method for a semiconductor wafer manufactured by film formation processing according to the embodiment of FIG. 1; and

FIGS. 5A-5D are schematic illustrations of a manufacturing method for a semiconductor wafer manufactured by film formation processing according to the embodiment of FIG. 1.

### DETAILED DESCRIPTION OF THE INVENTION

An embodiment of a semiconductor manufacturing apparatus according to the present invention will now be explained with reference to the accompanying drawings.

### Embodiment

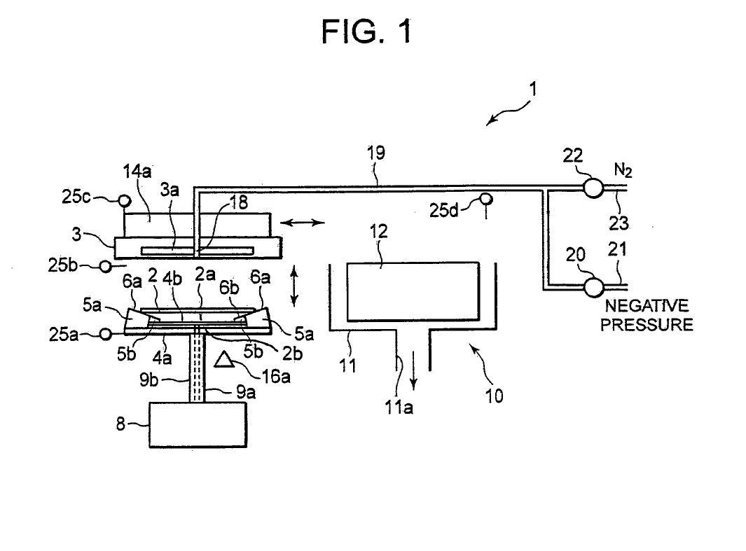

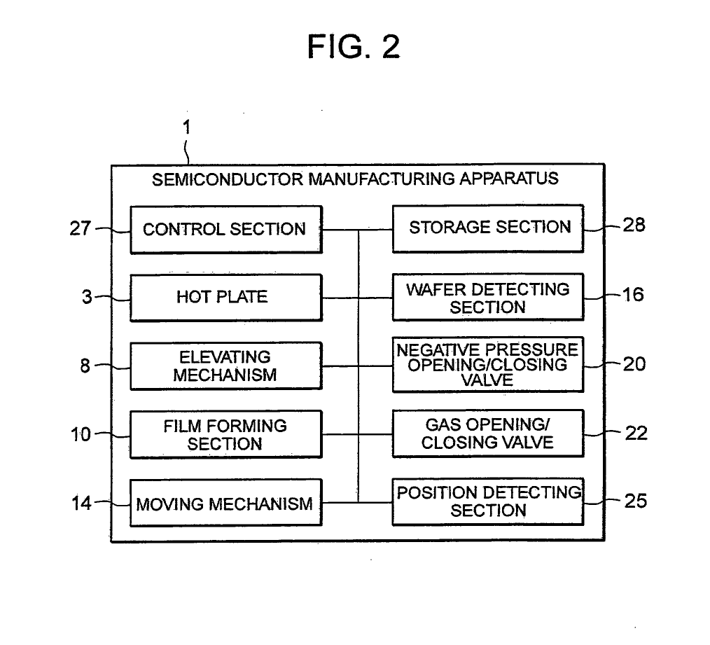

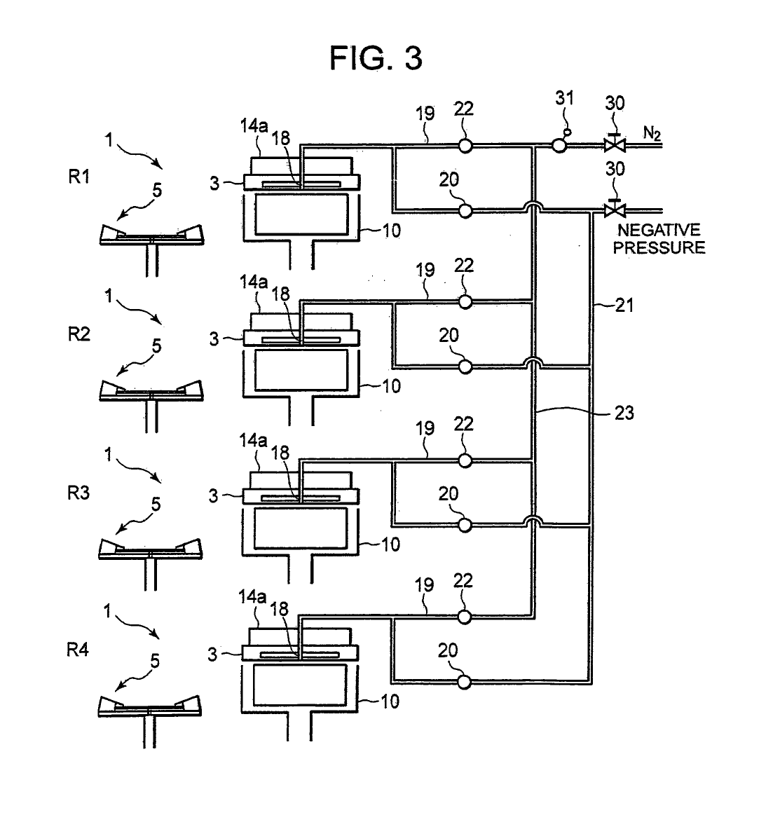

FIG. 1 is an explanatory drawing schematically illustrating a semiconductor manufacturing apparatus according to an embodiment of the invention. FIG. 2 is a block diagram showing the semiconductor manufacturing apparatus according to the embodiment of FIG. 1. FIG. 3 is an explanatory drawing schematically illustrating a piping system according to the embodiment of FIG. 1.

In FIGS. 1 and 2, reference numeral 1 denotes a semiconductor manufacturing apparatus which is a manufacturing apparatus used at a step of preheating a semiconductor wafer 2, e.g., a sapphire wafer, having, as shown inverted, a front surface 2a and a rear surface 2b at a relatively low atmospheric temperature in, e.g., ambient air and forming a film used for production of a semiconductor device in a state where the semiconductor wafer 2 has an increased temperature, and it is, e.g., an atmospheric CVD apparatus.

Reference numeral 3 denotes a hot plate that is a discoid member which includes a heating section 3a, e.g., an electric heater having a diameter equal to that of the semiconductor wafer 2, and has a diameter larger than that of the semiconductor wafer 2. The hot plate 3 is arranged above the semiconductor wafer 2 supported by a later-explained support portion 5 to face a rear surface 2b of the semiconductor wafer 2, preheats the semiconductor wafer 2, and is also used as a working bench in a process operation during a film forming step carried out in a state where the semiconductor wafer 2 has an increased temperature.

A support section includes a support base 4a which is formed by bonding a plurality of (e.g., three) arms at equal intervals to an outer diameter portion of a discoid support plate having a relatively small diameter arranged to face the hot plate 3 with a predetermined gap interposed there between. Each prism-like support portion 5a formed of, e.g., a quartz glass is disposed at a distal end of an arm formed on an outer side apart from the outer diameter of the semiconductor wafer 2. The support base 4a functions to support an outer peripheral part of the semiconductor wafer 2 by using an inclined surface 6a provided on the support portion 5a without inclining the semiconductor wafer 2.

Reference numeral 4b denotes a support base which is formed like the support base 4a and arranged on the hot plate 3 side of the support base 4a. Each support portion 5b has the same inclined surface 6b as that of the support portion 5a and is disposed at the distal end of an arm having substantially the same diameter as the outer diameter of the semiconductor wafer 2. The support base 4b functions to support an outer rim part of the semiconductor wafer 2 by using a distal end of the inclined surface 6b on the hot plate 3 side without inclining the semiconductor wafer 2.

The semiconductor wafer 2 according to this embodiment is supported by the support portions 5a or 5b (which will be referred to as the support portion 5 when these portions do not have to be discriminated from each other) in such a manner that a rear surface of the semiconductor wafer 2 faces the hot plate 3.

Reference numeral 8 denotes an elevating mechanism which functions to independently move up and down a cylindrical elevating shaft 9a, which has the support base 4a bonded at a distal end thereof, and a columnar elevating shaft 9b, which is inserted into an inner cylindrical side of the elevating shaft 9a and has the support base 4b bonded at a distal end thereof. The elevating mechanism 8 moves up and down the support portions 5a and 5b through the support bases 4a and 4b by using the respective elevating shafts 9a and 9b.

Reference numeral 10 designates a film forming section which includes a dispersion head 12 provided in a case-like reaction chamber 11 having an exhaust opening 11a provided therein. The film forming section 10 functions to deposit a reaction product dispersed from the dispersion head 12 onto a front surface 2a of the semiconductor wafer 2 to form a film used for production of a semiconductor device, e.g., an MOSFET (Metal Oxide Semiconductor Field Effect Transistor) based on the CVD method.

Reference numeral 14 denotes a moving mechanism with relatively high rigidity which includes a non-illustrated linear guide which moves a heater holder 14a having the hot plate 3 disposed there at, a driving mechanism for the linear guide, and others. The moving mechanism 14 functions to horizontally reciprocate the hot plate 3 on the support portion 5 and on the dispersion head 12 in the film forming section 10.

Reference numeral 16 designates a wafer detecting section which includes an optical wafer detection sensor 16a which detects reflected light of light emitted from a light emitting portion to detect whether the semiconductor wafer 2 is present on the support portion 5.

Reference numeral 18 denotes a suction/discharge hole which is a through hole formed to pierce a central part of the hot plate 3 in a thickness direction thereof. The suction/discharge hole 18 functions as a suction hole through which a negative pressure required to suck and hold the semiconductor wafer 2 is supplied and as an ejection hole through which a gas (a nitrogen gas in this embodiment) which controls a temperature of the semiconductor wafer 2 at a preheating step is ejected, and connected with an introduction tube 19 through which the negative pressure and the nitrogen gas are supplied.

Introduction tube 19 is a pipe formed of a material which can follow up movement of the hot plate 3 and does not collapse due to the negative pressure or a composite material such as a resin material. The introduction tube 19 has a structure where a negative pressure supply tube 21 through which the negative pressure is supplied via a negative pressure opening/closing valve 20 is connected with a gas supply tube 23 through which the nitrogen gas is supplied via a gas opening/closing valve 22 so that the respective ducts join together between the negative pressure opening/closing valve 20, the gas opening/closing valve 22, and the suction/discharge hole 18.

Each of the negative pressure opening/closing valve 20 and the gas opening/closing valve 22 is an ON-OFF valve such as a two-way solenoid valve and functions to open and close each duct.

Reference numeral 25 designates a position detecting section which includes mechanical position detecting sensors 25a to 25d, e.g., limit switches. The position detecting section 25 functions to detect that the support portion 5 is placed at a lower position by the position detecting sensor 25a, that the support portion 5 is placed at an upper position by the position detecting sensor 25b, that the hot plate 3 is placed on the support portion 5 by the position detecting sensor 25c, and that the hot plate 3 is placed on the film forming section 10 by the position detecting sensor 25d.

Reference numeral 27 denotes a control section of the semiconductor manufacturing apparatus 1 which controls each section in the semiconductor manufacturing apparatus 1 to execute, e.g., film formation processing.

Reference numeral 28 designates a storage section which stores a program executed by the control section 27, various kinds of data used in the program, results of processing executed by the control section 27, and others.

As shown in FIG. 3, the piping system through which the negative pressure and the nitrogen gas are supplied is connected in such a manner that a non-illustrated single negative pressure supply source and a single gas supply source respectively distribute and supply the negative pressure and the nitrogen gas to each semiconductor manufacturing apparatus 1 which is one of four R1 to R4 semiconductor apparatuses 1. A closable flow regulating valve 30, which adjusts a supply amount of the negative pressure or the nitrogen gas, is provided on an upstream side of diverging points of the negative pressure supply tube 21 and the gas supply tube 23 extending to each semiconductor manufacturing apparatus 1. A regulator 31, which maintains a pressure of the supplied nitrogen gas constant, is provided between the flow regulating valve 30 of the gas supply tube 23 and the diverging point on the downstream side.

The storage section 28 of the semiconductor manufacturing apparatus 1 stores a film formation processing program which functions to execute a preheating step, a film forming step, and a foreign particle removing step. At the preheating step, the semiconductor wafer 2 is carried to the support portion 5 and is preheated by the hot plate 3 while controlling the increasing temperature by using nitrogen gas released through the suction/discharge hole 18. At the film forming step, the preheated semiconductor wafer 2 is sucked and held by utilizing the negative pressure supplied to the suction/discharge hole 18, is moved to the film forming section 10, and a reaction production is deposited on the front surface 2a of the semiconductor wafer 2 by the dispersion head 12 to form a film used for production of the semiconductor device based on a CVD method. At the foreign particle removing step, the semiconductor wafer 2 after film formation is moved and placed on the support portion 5. Then, the hot plate 3, which does not hold the semiconductor wafer 2, is moved to the film forming section 10 during a waiting time until the next semiconductor wafer 2 is carried in, and nitrogen gas is intermittently ejected from the suction/discharge hole 18 to remove foreign particles which might have been sucked into the introduction tube 19. The steps in the film formation processing program executed by the control section 27 form respective functional means employing hardware of the semiconductor manufacturing apparatus according to this embodiment.

Furthermore, the storage section 28 also stores sequence data including an opening time during which the nitrogen gas is ejected, such as with intermittent ejection of the nitrogen gas at the foreign particle removing step, and a closing time during which the nitrogen gas is blocked written therein.

The film formation processing program, the sequence data, and others are recorded in a recording medium, e.g., a CD and are provided in this state. They are installed in advance in the storage section 28 of the semiconductor manufacturing apparatus 1 using a non-illustrated reading device for the recording medium.

The semiconductor wafer 2 according to this embodiment is a sapphire wafer using a sapphire substrate having an exemplary diameter of 6 inches and an exemplary thickness of 0.6 mm. It is positioned in such a manner that a gap between the rear surface 2b of the semiconductor wafer 2 and the lower surface of the hot plate 3 becomes 3 mm when its outer peripheral part is supported on the inclined surfaces 6a of the support portion 5.

Moreover, the temperature of the hot plate 3 is set to 385° C., the flow regulating valve 30 of the gas supply tube 23 is fully opened, a supply pressure of the nitrogen gas is set to 40 KPa by the regulator 31, and the flow regulating valve 30 of the negative pressure supply tube 21 is adjusted in advance to a valve travel with which a suction force required to hold the semiconductor wafer 2 does not become excessive.

Additionally, an opening time in the sequence data is set to 30 seconds and a closing time in the sequence data is set to 3 seconds.

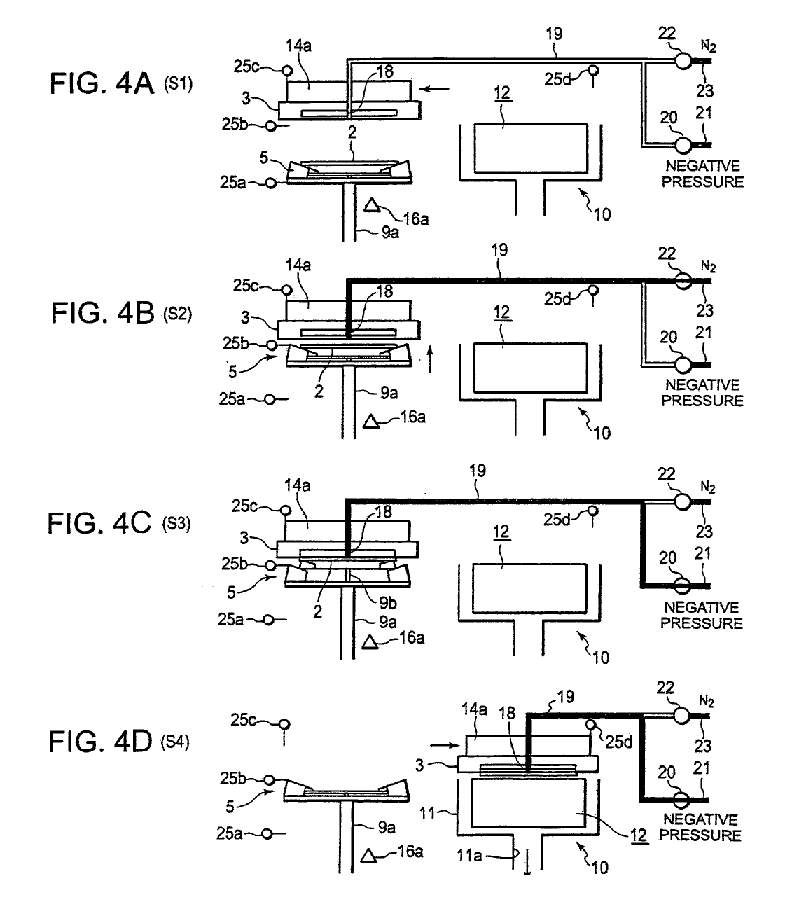

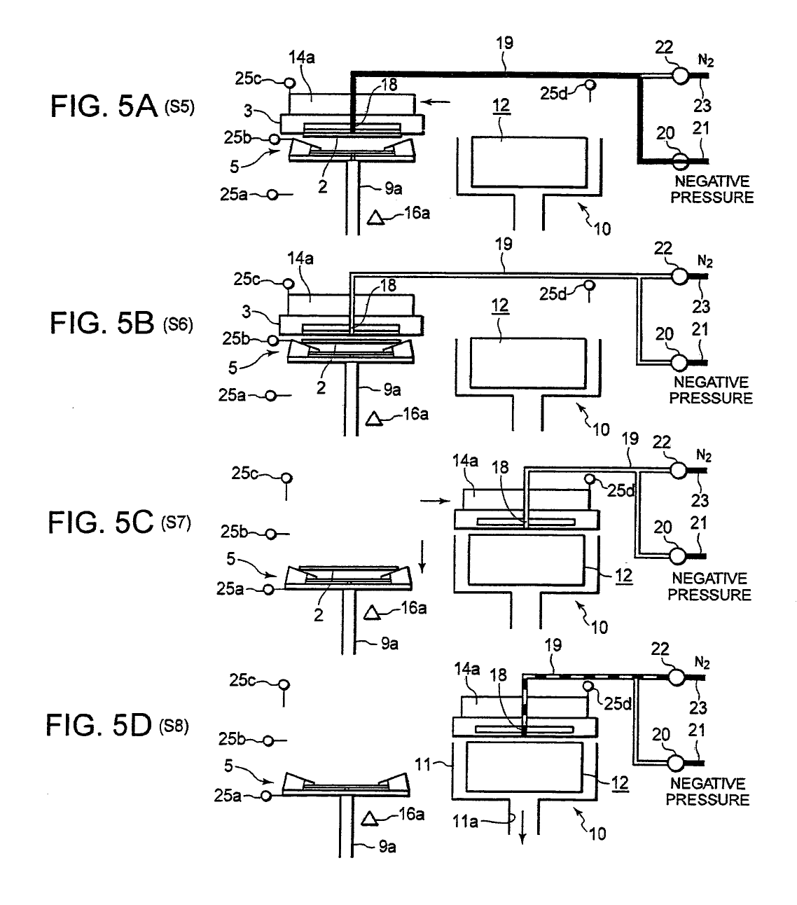

The film forming processing according to this embodiment and the manufacturing method of the semiconductor wafer manufactured based on this film formation processing will now be explained hereinafter with reference to the steps indicated by S1 thru S4 in FIGS. 4A thru 4D and by S4 thru S8 in FIGS. 5A thru 5D.

At S1 in FIG. 4A, the control section 27 in the semiconductor manufacturing apparatus 1 is in a standby mode (see a later-explained step S8 in FIG. 5D) until a new semiconductor wafer 2 is carried to the support portion 5 by a non-illustrated carrier robot while intermittently ejecting the nitrogen gas from the suction/discharge hole 18 in the hot plate 3 which has been moved to the film forming section 10 based on the film formation processing program. When the wafer detection sensor 16a in the wafer detecting section 16 detects that the new semiconductor wafer is carried to the support portion 5, a closing signal is supplied to the gas opening/closing valve 22 to close the gas opening/closing valve 22, thereby stopping intermittent ejection of the nitrogen gas. At this time, the negative pressure opening/closing valve 20 is held in the closed state.

Further, the control section 27 moves the hot plate 3 disposed in the heater holder 14a toward the support portion 5 by using the moving mechanism 14, stops this movement upon receiving a detection signal from the position detection sensor 25c in the position detecting section 25, and stops the hot plate 3 on the support portion 5.

At S2 in FIG. 4B, the control section 27 which has stopped the hot plate 3 on the support portion 5 simultaneously moves up the elevating shafts 9a and 9b by using the elevating mechanism 8, stops this upward movement upon receiving a detection signal from the position detection sensor 25b, and stops the rear surface 2b of the semiconductor wafer 2 whose outer peripheral part is supported on the inclined surfaces 6a of the support portions 5a at a position above the support portion 5 which is 3 mm apart from the lower surface of the hot plate 3.

Further, the control section 27 heats the hot plate 3 to a predetermined set temperature (385° C. in this exemplary embodiment), and transmits heat from the rear surface 2b of the semiconductor wafer 2 to increase the temperature of the semiconductor wafer 2. The control section 27 also supplies an opening signal to the gas opening/closing valve 22 to open the gas opening/closing valve 22, and ejects nitrogen gas toward the rear surface 2b of the semiconductor wafer 2 from the suction/discharge hole 18 opened at the central part of the hot plate 3, the nitrogen gas being supplied from the gas supply tube 23 via the introduction tube 19, thereby controlling the temperature increase of the semiconductor wafer 2.

A temperature difference occurs in the semiconductor wafer 2 between the rear surface 2b close to the hot plate 3 and the front surface 2a exposed to room temperature due to heating from one direction by this hot plate 3, and convex warping would be expected to occur on the rear surface 2b side of wafer 2. However, at the preheating step according to this embodiment, since nitrogen gas is ejected at the central part of rear surface 2b of the semiconductor wafer 2 from the suction/discharge hole 18 to control the rate of temperature increase of the semiconductor wafer, uniform preheating can be carried out while suppressing warping of the semiconductor wafer 2.

At S3 in FIG. 4C, a non-illustrated temperature sensor monitors an increase in the temperature of the entire semiconductor wafer 2 to a uniform temperature to reach a predetermined preheating temperature (e.g., 330° C.), and the control section 27 opens the gas opening/closing valve 22 to interrupt ejection of nitrogen gas when the semiconductor wafer 2 is preheated to the predetermined preheating temperature or above. Furthermore, the control section 27 moves up the elevating shaft 9b by using the elevating mechanism 8 to bring the rear surface 2b of the semiconductor wafer 2 whose outer rim part is supported at the distal end of each support portion 5b into contact with the lower surface of the hot plate 3. After elapse of a predetermined time (e.g., 120 seconds), the control section 27 opens the negative pressure opening/closing valve 20 to suck and hold the semiconductor wafer 2 on the hot plate 3 by utilizing the negative pressure supplied to the suction/discharge hole 18 from the negative pressure supply tube 21 via the introduction tube 19.

At S4 in FIG. 4D, the control section 27 which allows the semiconductor wafer 2 to be sucked and held on the hot plate 3 moves down the elevating shaft 9b by using the elevating mechanism 8 to return each support portion 5b to its original position, moves the hot plate 3 sucking and holding the semiconductor wafer 2 toward the film forming section 10 by the moving mechanism 24, stops this movement upon receiving a detection signal from the position detection sensor 25d in the position detecting section 25, and stops the hot plate 3 on the dispersion head 12 in the film forming section 10.

Moreover, the control section 27 retains the semiconductor wafer 2 to be sucked and held by the hot plate 3, and deposits a predetermined reaction product on the front surface 2a of the semiconductor wafer 2 by using the dispersion head 12 while ventilating the inside of the reaction chamber 11 through the exhaust opening 11a in the film forming section 10, thereby forming a predetermined film on the front surface 2a of the semiconductor wafer 2.

At this time, foreign particles composed of the reaction product might be sucked into the introduction tube 19 by the negative pressure from the small gap between the rear surface 2b of the semiconductor wafer 2 sucked and held by the hot plate 3 and the hot plate 3, and the foreign particles then remain in the introduction tube 19.

At S5 in FIG. 5A, the control section 27 which has been subjected to the film forming step moves the hot plate 3 toward the support portion 5 by utilizing the moving mechanism 14 while sucking and holding the semiconductor wafer 2 by the hot plate 3 after film formation, stops this movement upon receiving a detection signal from the position detection sensor 25c in the position detecting section 25, and stops the hot plate 3 on the support portion 5.

At S6 in FIG. 5B, the control section 27 which has stopped the hot plate 3 sucking and holding the semiconductor wafer 2 on the support portion 5 closes the negative pressure opening/closing valve 20 to interrupt supply of the negative pressure, and then opens the gas opening/closing valve 22 to restore the negative pressure in the introduction tube 19 to a normal pressure. Subsequently, the control section 27 closes the gas opening/closing valve 22 to interrupt supply of the nitrogen gas, and drops the semiconductor wafer 2 released from being held by suction by the hot plate 3 onto the support portion 5 so that the semiconductor wafer 2 is supported on the inclined surface 6a of each support portion 5a.

At S7 in FIG. 5C, the control section 27 which has dropped the semiconductor wafer 2 onto the support portion 5 simultaneously moves down the elevating shafts 9a and 9b by using the elevating mechanism 8, and stops this downward movement upon receiving a detection signal from the position detection sensor 25a. The control section 27 stops the semiconductor wafer 2 supported by the support portion 5 at a position below the support portion 5 apart from the hot plate 3, and moves the hot plate 3 toward the film forming section 10 by the moving mechanism 14. The control section stops this movement upon receiving a detection signal from the position detection sensor 25d in the position detecting section 25, and stops the hot plate 3 which does not suck and hold the semiconductor wafer 2 on the film forming section 10.

It is to be noted that the semiconductor wafer 2 on the support portion 5 stopped at the lower position is then carried to the next step by a non-illustrated carrier robot.

At S8 in FIG. 5D, when it is determined that the hot plate 3 is placed at the film forming section 10 and the semiconductor wafer 2 is not held by the hot plate 3, the control section 27 intermittently ejects nitrogen gas from the suction/discharge hole 18 in the hot plate 3 placed on the film forming section 10 while ventilating the inside of the reaction chamber 11 through the exhaust opening 11a in the film forming section 10, thereby discharging and removing any foreign particles remaining in the introduction tube 19.

The determination (judgment) in this case is executed in the following manner.

That is, the control section 27 determines (judges) whether the hot plate 3 is placed on the film forming section 10 based on the presence or absence of a detection signal from the position detection sensor 25d, and it determines that the hot plate 3 is placed on the film forming section 10 when it receives the detection signal from the position detection sensor 25d.

Furthermore, the control section 27 determines (judges) whether the semiconductor wafer 2 is held by the hot plate 3 based on the opened or closed state of the negative pressure opening/closing valve 20, and determines that the semiconductor wafer 2 is not held by the hot plate 3 based on the fact that the negative pressure opening/closing valve 20 is closed, i.e., that the negative pressure is not supplied.

Moreover, intermittent ejection of nitrogen gas in this case is executed as follows.

The control section 27 reads the sequence data stored in the storage section 28 to recognize an opening time and a closing time written in the sequence data.

Additionally, the gas opening/closing valve 22 is opened to start ejection of nitrogen gas from the suction/discharge hole 18 in the hot plate 3 placed on the film forming section 10. The control section 27 monitors the recognized closing time in the sequence data while measuring an elapsed time from start of ejection of the nitrogen gas by using a clock function. When the elapsed time exceeds the opening time, the control section 27 closes the gas opening/closing valve 22 to interrupt supply of the nitrogen gas to the suction/discharge hole 18, and starts re-measurement of the elapsed time to monitor elapse of the recognized closing time in the sequence data while measuring the elapsed time after interruption. When the elapsed time exceeds the closing time, the control section 27 again opens the gas opening/closing valve 22 to start supply of nitrogen gas to the suction/discharge hole 18.

As explained above, the control section 27 enters the standby mode until the next semiconductor wafer 2 is carried to the support portion 5 by the non-illustrated carrier robot while continuing intermittent ejection of the nitrogen gas. When the wafer detection sensor 16a in the wafer detecting section 16 detects that the semiconductor wafer 2 has been carried in, the controls section 27 stops intermittent ejection of gas and returns to step S1 to start film formation processing with respect to the semiconductor wafer 2.

In this manner, a predetermined film used in production of the semiconductor device is formed on the front surface 2a of the semiconductor wafer 2 based on the film formation processing by the semiconductor manufacturing apparatus 1 according to this embodiment.

It is to be noted that, when nitrogen gas from the single gas supply source is distributed to the plurality of semiconductor manufacturing apparatuses 1 through the piping system depicted in FIG. 3 and the film is formed while supplying the semiconductor wafer 2 by the single carrier robot, the R2 semiconductor manufacturing apparatus 1 performs the film forming step while the R1 semiconductor manufacturing apparatus 1 carries out the preheating step, and the R3 and R4 semiconductor manufacturing apparatuses 1 effect intermittent ejection of nitrogen gas at the film forming section 10 at the foreign particle removing step. Therefore, the respective semiconductor manufacturing apparatuses 1 perform the different steps.

At this time, since ejection of the nitrogen gas for removal of foreign particles remaining in the introduction tube 19 at the foreign particle removing step according to this embodiment is intermittently performed, the amount of nitrogen gas supplied can be reduced and the pressure can be prevented from fluctuating when the semiconductor manufacturing apparatus 1 at the preheating step ejects nitrogen gas, thereby smoothly suppressing warping of the semiconductor wafer 2 at the preheating step.

As explained above, in the film formation processing according to this embodiment, the semiconductor wafer 2 after film formation is moved and positioned on the support portion 5, then the hot plate 3 which does not hold the semiconductor wafer 2 is moved to the film forming section 10 in the waiting time until the next semiconductor wafer 2 is carried in, and the nitrogen gas released through the suction/discharge hole 18 is used to remove any foreign particles which might have been sucked into and might remain in the introduction tube 19 at the film forming step. Therefore, at the preheating step, when nitrogen gas, which is used to control the increase in temperature of the semiconductor wafer 2, is ejected toward the rear surface 2b of the semiconductor wafer 2 from the suction/discharge hole 18, any foreign particles present are not discharged to adhere to the front surface 2a or the rear surface 2b of the semiconductor wafer 2, and quality of film formation on the semiconductor wafer 2 can be improved thereby enhancing yield ratio.

Additionally, the state where the hot plate 3 placed above the film forming section 10 does not hold the semiconductor wafer 2 is determined based on the state where the negative pressure is not supplied, i.e., the state where the negative pressure opening/closing valve 20 is closed. Therefore, the presence or absence of the semiconductor wafer 2 on the hot plate 3 can be determined without using an optical or mechanical sensor which would be hard to install in the reaction chamber 11 filled with a reaction product.

It is to be noted that the example where ejection of nitrogen gas for removal of any foreign particles remaining in the introduction tube 19 at the foreign particle removing step is intermittently carried out has been explained in the foregoing embodiment, but the nitrogen gas may be continuously ejected when a single semiconductor manufacturing apparatus 1 performs the film formation processing. That is because the ejection pressure of the nitrogen gas at the preheating step is not influenced even if such a structure is adopted.

Further, although the example where whether the hot plate 3 placed above the film forming section 10 holds the semiconductor wafer 2 is determined based on the opened/closed state of the negative pressure opening/closing valve 22 has been explained, a pressure sensor may be provided to the introduction tube 19 and a pressure detected by this sensor may be used to determine whether the hot plate 3 holds the semiconductor wafer 2.

As explained above, in this embodiment, when the hot plate which has the suction/discharge hole serving as the suction hole through which the negative pressure used to suck and hold the semiconductor wafer is supplied and also serves as the ejection hole through which the nitrogen gas used to control the temperature of the semiconductor wafer is ejected is placed on the film forming section and the hot plate does not hold the semiconductor wafer, the nitrogen gas is ejected from the suction/discharge hole. Therefore, any foreign particles sucked to and remaining in the introduction tube at the film forming step can be removed by the nitrogen gas ejected from the suction/discharge hole when the semiconductor wafer is not present. Moreover, it is possible to avoid discharge of any foreign particles present when the nitrogen gas used to control the increasing temperature of the semiconductor wafer is ejected from the suction/discharge hole at the preheating step, any foreign particles can be prevented from adhering to the front surface or the rear surface of the semiconductor wafer, and quality of film formation on the semiconductor wafer can be improved thereby enhancing yield ratio.

Additionally, when ejecting nitrogen gas from the suction/discharge hole, the nitrogen gas may be intermittently ejected. As a result, the amount of nitrogen gas supplied can be reduced when distributing the nitrogen gas from the single gas supply source to the plurality of semiconductor manufacturing apparatuses, and pressure of the nitrogen gas supplied to the semiconductor manufacturing apparatus performing the other step can be prevented from fluctuating.

Further, it is to be noted that while nitrogen gas has been given as the example of the gas ejected to control the increasing temperature of the semiconductor wafer in conjunction with the foregoing embodiment, any gas can be used as long as it is an inert gas, e.g., argon (Ar).

Further, although the semiconductor wafer carried to the semiconductor manufacturing apparatus has been exemplified as a sapphire wafer in the foregoing embodiment, the semiconductor wafer is not restricted thereto and it may be, e.g., a semiconductor wafer having an SOI structure in which a thin-film element forming layer composed of silicon is formed on a silicon substrate to interpose a buried oxide film there between. That is, any semiconductor wafer can obtain the same effect as long as it is a semiconductor wafer that requires ejection of a gas which suppresses warping at the preheating step and also requires film formation on the sucked and held semiconductor wafer.

Furthermore, although the semiconductor manufacturing apparatus has been exemplified as an atmospheric CVD apparatus in the foregoing embodiment, the semiconductor manufacturing apparatus is not restricted thereto and it may be, e.g., a decompression CVD apparatus. That is, any semiconductor manufacturing apparatus can obtain the same effect as long as it is a semiconductor manufacturing apparatus that performs ejection of a gas which suppresses warping from the suction/discharge hole when preheating the semiconductor wafer and carries out film formation on the semiconductor wafer sucked and held by the negative pressure supplied to the suction/discharge hole.

It is understood that various other modifications will be apparent to and can be readily made by those skilled in the art without departing from the scope and spirit of the present invention. Accordingly, it is not intended that the scope of the claims appended hereto be limited to the description set forth above but rather that the claims be construed as encompassing all of the features of patentable novelty which reside in the present invention, including all features which would be treated as equivalents.

What is claimed is:

1. A semiconductor manufacturing apparatus, comprising:
a hot plate which heats and holds a semiconductor wafer, the hot plate having a hole through which both a negative pressure is applied and a gas is ejected, the negative pressure being applied to suck and hold a rear surface of the semiconductor wafer, the gas being ejected to control an increase in temperature of the semiconductor wafer when the hot plate heats the semiconductor wafer; and
a film forming section which forms a film on a front surface of the semiconductor wafer,
wherein the gas is further ejected from the hole when the hot plate is placed at the film forming section and the hot plate does not hold the semiconductor wafer.

2. The semiconductor manufacturing apparatus according to claim 1, further comprising a support section which supports the semiconductor wafer when the hot plate heats the semiconductor wafer and the gas is ejected to control the increase in temperature of the semiconductor wafer.

3. The semiconductor manufacturing apparatus according to claim 2, wherein after the hot plate heats the semiconductor wafer, the negative pressure is applied so that the hot plate holds the semiconductor wafer, and the hot plate and wafer are transported from the support section to the film forming section.

4. The semiconductor manufacturing apparatus according to claim 3, wherein the film forming section includes a reaction chamber having an exhaust opening, and a dispersion head disposed in the reaction chamber, the dispersion head depositing a reaction product to form the film on the front surface of the semiconductor wafer, while the reaction chamber is ventilated through the exhaust opening.

5. The semiconductor manufacturing apparatus according to claim 4, further comprising an introduction tube coupled to the hole in the hot plate, and through which the negative pressure is applied and the gas is supplied, wherein after the film is formed, the semiconductor wafer is transported back to the support section, and while the hot plate is at the film forming section and the hot plate does not hold the semiconductor wafer, the gas is further ejected from the hole, so that foreign particles in the hole and introduction tube are ejected therefrom, and subsequently ventilated through the exhaust opening.

6. The semiconductor manufacturing apparatus according to claim 1, wherein the gas is an inert gas.

7. The semiconductor manufacturing apparatus according to claim 1, wherein the gas is intermittently ejected from the hole.

8. The semiconductor manufacturing apparatus according to claim 1, further comprising a support section that includes a first support plate that supports the semiconductor wafer when the hot plate heats the semiconductor wafer and the gas is ejected during to control the increase in temperature of the semiconductor wafer, and a second support plate that is movable relative to the first support plate and that supports the semiconductor wafer when the second support plate is moved away from the first support plate, and that positions the semiconductor wafer closer to the hot plate to allow the hot plate to hold the semiconductor wafer when the negative pressure is applied.

9. A semiconductor manufacturing apparatus, comprising:
a hot plate which heats and holds a semiconductor wafer, the hot plate having a hole through which both a negative pressure is applied and a gas is ejected, the negative pressure being applied to suck and hold a rear surface of the semiconductor wafer, the gas being ejected to control an increase in temperature of the semiconductor wafer when the hot plate heats the semiconductor wafer;
a film forming section which forms a film on a front surface of the semiconductor wafer while the rear surface is sucked and held by the hot plate;
means for determining whether or not the hot plate is placed on the film forming section;
means for determining whether or not the semiconductor wafer is held by the hot plate; and
means for further ejecting the gas through the hole of the hot plate when both the hot plate is determined to have been placed on the film forming section and the semiconductor wafer is determined to be not held by the hot plate.

10. The semiconductor manufacturing apparatus according to claim 9, further comprising means for storing sequence data, including an opening time during which the gas is ejected and a closing time during which a flow of the gas is interrupted; and wherein the means for further ejecting the gas through the hole includes means for reading the sequence data, and means for intermittently ejecting the gas from the hole based on the sequence data read.

11. The semiconductor manufacturing apparatus according to claim 9, wherein the means for determining whether or not the semiconductor wafer is held by the hot plate includes determining whether the negative pressure is being applied, and wherein when it is determined that the negative pressure is being applied, it is determined that the semiconductor wafer is held by the hot plate, and when it is determined that the negative pressure is not being applied, it is determined that the semiconductor wafer is not held by the hot plate.

12. A method of manufacturing a semiconductor wafer, comprising:
providing a hot plate which heats and holds the semiconductor wafer, the hot plate having a hole through which both a negative pressure is applied and a gas is ejected, the negative pressure being applied to suck and hold a rear surface of the semiconductor wafer, the gas being ejected to control an increase in temperature of the semiconductor wafer when the hot plate heats the semiconductor wafer;
providing a film forming section which forms a film on a front surface of the semiconductor wafer while the rear surface is sucked and held by the hot plate;
detecting whether or not the hot plate is placed on the film forming section;
detecting whether or not the semiconductor wafer is held by the hot plate; and
further ejecting the gas from the hole of the hot plate when both the hot plate is placed on the film forming section and the semiconductor wafer is not held by the hot plate.

13. The method of manufacturing a semiconductor wafer according to claim 12, wherein the further ejecting the gas from the hole includes intermittently ejecting the gas from the hole.

14. The method of manufacturing a semiconductor wafer according to claim 12, further comprising providing a support section, which supports the semiconductor wafer when the hot plate heats the semiconductor wafer and the gas is ejected to control the increase in temperature of the semiconductor wafer.

25. The method of manufacturing a semiconductor wafer according to claim 14, further comprising applying the negative pressure after the hot plate heats the semiconductor wafer, so that the hot plate holds the semiconductor wafer, and transporting the hot plate and wafer from the support section to the film forming section.

16. The method of manufacturing a semiconductor wafer according to claim 15, wherein the film forming section includes a reaction chamber having an exhaust opening, and a dispersion head disposed in the reaction chamber, the dispersion head depositing a reaction product to form the film on the front surface of the semiconductor wafer, while the reaction chamber is ventilated through the exhaust opening.

17. The method of manufacturing a semiconductor wafer according to claim 16, further comprising providing an introduction tube coupled to the hole in the hot plate, and through which the negative pressure is applied and the gas is supplied; transporting the semiconductor wafer back to the support section after the film is formed; locating the hot plate at the film forming section without the semiconductor wafer held thereby; and further ejecting the gas through the hole while the hot plate is placed at the film forming section without the semiconductor wafer, so that foreign particles in the hole and introduction tube are ejected therefrom, and subsequently ventilated through the exhaust opening.

18. A recording medium having a program which is recorded therein and which is executed by a control section of a semiconductor manufacturing apparatus, the semiconductor manufacturing apparatus being comprised of a hot plate which heats and holds a semiconductor wafer, the hot plate having a hole through which both a negative pressure is applied and a gas is ejected, the negative pressure being applied to suck and hold a rear surface of the semiconductor wafer, the gas being ejected to control an increase in temperature of the semiconductor wafer when the hot plate heats the semiconductor wafer; and a film forming section which forms a film on a front surface of the semiconductor wafer while the rear surface is sucked and held by the hot plate, the program comprising:
determining whether or not the hot plate is placed on the film forming section;
determining whether or not the semiconductor wafer is held by the hot plate; and
further ejecting the gas through the hole of the hot plate when it is determined that both the hot plate has been placed at the film forming section and the semiconductor wafer is not held by the hot plate

19. The recording medium according to claim 18, wherein the program includes sequence data, including an opening time during which the gas is ejected and a closing time during which a flow of the gas is interrupted; and wherein the further ejecting the gas from the hole includes reading the sequence data, and intermittently ejecting the gas from the hole based on the sequence data read.

20. The recoding medium according to claim 18, wherein determining whether or not the semiconductor wafer is held by the hot plate includes determining whether the negative pressure is being applied, and wherein when it is determined that the negative pressure is being applied, it is determined that the semiconductor wafer is held by the hot plate, and when it is determined that the negative pressure is not being applied, it is determined that the semiconductor wafer is not held by the hot plate.
